(19) United States
(12) Patent Application Publication
(10) Pub. No.: US 2021/0381097 A1
(43) Pub. Date: Dec. 9, 2021

(54) VAPOR DEPOSITION APPARATUS AND METHOD FOR COATING A SUBSTRATE IN A VACUUM CHAMBER

(71) Applicant: Applied Materials, Inc., Santa Clara, CA (US)

(72) Inventors: Stefan BANGERT, Steinau (DE); Wolfgang BUSCHBECK, Hanau (DE)

(21) Appl. No.: 17/332,871

(22) Filed: May 27, 2021

Related U.S. Application Data
(60) Provisional application No. 63/034,627, filed on Jun. 4, 2020.

(51) Int. Cl. C23C 14/24; C23C 14/54

(52) U.S. Cl. CPC C23C 14/243; C23C 14/548

(57) ABSTRACT

A crucible for flash evaporation of a liquid material is described. The crucible includes one or more sidewalls and a reservoir portion below the one or more sidewalls, the reservoir portion of having a first cross-section of a first size and a second cross-section above the first cross-section of a second size, the second size being larger than the first size.

### CROSS-REFERENCE TO RELATED APPLICATIONS

This application claims benefit of U.S. Provisional Patent Application Ser. No. 63/034,627, filed on Jun. 4, 2020, which is herein incorporated by reference in its entirety.

### TECHNICAL FIELD

Embodiments of the present disclosure relate to substrate coating by thermal evaporation in a vacuum chamber. Embodiments of the present disclosure further relate to coating by flash evaporation. Embodiments also relate to coating of alkali metals and/or alkaline earth metals, such as lithium. Specifically, embodiments relate to a crucible for flash evaporation of a liquid material, a vapor deposition apparatus, method of coating a substrate in a vacuum chamber, and a method of manufacturing an anode of a battery.

### BACKGROUND

Various techniques for deposition on a substrate, for example, chemical vapor deposition (CVD) and physical vapor deposition (PVD) are known. For deposition at high deposition rates, thermal evaporation may be used as a PVD process. For thermal evaporation, a source material is heated up to produce a vapor that may be deposited, for example, on a substrate. Increasing the temperature of the heated source material increases the vapor concentration and can facilitate high deposition rates. The temperature for achieving high deposition rates depends on the source material physical properties, e.g. vapor pressure as a function of temperature, and substrate physical limits, e.g. melting point.

For example, the source material to be deposited on the substrate can be heated in a crucible to produce vapor at an elevated vapor pressure. The vapor can be transported from the crucible to a coating volume in a heated manifold. The source material vapor can be distributed from the heated manifold onto a substrate in a coating volume, for example, a vacuum chamber.

Modern thin film lithium batteries may include a lithium layer. The lithium layer is formed, for example, through the deposition of lithium in a vapor state on the substrate. Since lithium is highly reactive, a plurality of measures needs to be addressed to operate and maintain such deposition systems.

For alkali and/or alkaline earth metals, some arrangements are not so amenable to high volume and low-cost manufacturing because, the methods have serious challenges in managing the high reactivity of the materials, while scaling to high volume production. This presents challenges in producing uniformly deposited pure lithium. Highly reactive materials, especially lithium, can easily be oxidized in reaction with ambient surroundings, e.g., gases, materials, etc. Lithium is of particular interest since lithium is suitable for the production of higher energy density batteries and accumulators, i.e. primary batteries and secondary batteries.

Common deposition systems for lithium, and other alkali metals or alkaline earth metals, respectively, may utilize sputter sources or conventional evaporation sources and methods of operating thereof. Sputtering methods for lithium are challenging, particular with respect to costs and manufacturability, in light of the reactivity of lithium. The high reactivity at first influences the manufacturing of the target, which is a necessary component for sputtering, and secondly influences the handling of the resulting targets. Since the melting point of lithium is relatively low, at 183° C., the deposition rate can also be limited as the melting point limits against a high-power density sputtering regime, a more amenable regime for high volume and lower cost manufacturing. In other words, the low melting point of lithium limits the maximum power which can be applied and therefore, the maximum deposition rate which can be achieved.

Accordingly, it is advantageous to have an improved crucible, an improved vapor deposition apparatus and an improved method of manufacturing an electrode of a thin film battery.

### SUMMARY

In light of the above, a vapor deposition apparatus and a method for coating a substrate in a vacuum chamber according to the independent claims are provided. Further aspects, advantages and features of the present disclosure are apparent from the description and the accompanying drawings.

According to one embodiment, a crucible for flash evaporation of a liquid material is provided. The crucible includes one or more sidewalls and a reservoir portion below the one or more sidewalls, the reservoir portion of having a first cross-section of a first size and a second cross-section above the first cross-section of a second size, the second size being larger than the first size.

According to one embodiment, a vapor deposition apparatus is provided. The vapor deposition apparatus includes a crucible according to any of the embodiments of the present disclosure.

According to one embodiment, a vapor deposition apparatus configured to evaporate an alkali metal and/or alkaline earth metals, particularly lithium, is provided. The vapor deposition apparatus includes a flow meter with a measuring unit external to a conduit for the liquid material.

According to one embodiment, a method of coating a substrate in a vacuum chamber is provided. The method includes guiding a liquid material into a crucible for flash evaporation, particularly a crucible according to any of the embodiments of the present disclosure, flash evaporating the liquid material in the crucible, and measuring a flow rate of the liquid material to control a deposition rate of the material on the substrate.

According to one embodiment, a method of manufacturing an anode of a battery is provided. The method of manufacturing an anode of a battery includes a method for coating a substrate in a vacuum chamber according to any of the embodiments described herein.

According to one embodiment, a method of manufacturing an anode of a battery is provided. The method of manufacturing an anode of a battery includes guiding a web comprising or consisting of an anode layer in a vapor deposition apparatus according to any of the embodiments of the present disclosure and depositing a lithium containing material or lithium on the web with the vapor deposition apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments.

The accompanying drawings relate to embodiments of the disclosure and are described in the following:

FIG. 1 shows a schematic view of a vapor deposition apparatus having a flow meter according to embodiments of the present disclosure and a flow valve according to embodiments of the present disclosure;

FIG. 2 shows a schematic view of a crucible for flash evaporation according to embodiments of the present disclosure;

FIGS. 3A to 3C show schematic cross-sections of a crucible according to embodiments described herein and providing a self-regulating fill height;

FIG. 4 shows a schematic view of a vapor deposition apparatus having an evaporator according to embodiments of the present disclosure;

FIG. 5 shows a schematic view of an evaporator according to embodiments of the present disclosure;

FIG. 6 shows a flowchart for illustrating a method of coating a substrate in a vacuum chamber according to embodiments described herein;

FIG. 7 shows a flowchart for illustrating a method of manufacturing an anode of a battery according to embodiments described herein; and

FIG. 8 shows a schematic view of an evaporator according to embodiments of the present disclosure.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Within the following description of the drawings, the same reference numbers refer to the same or similar components. Generally, only the differences with respect to the individual embodiments are described. Unless specified otherwise, the description of a part or aspect in one applies to a corresponding part or aspect in another embodiment as well.

Embodiments of the present disclosure relate to vapor deposition, for example, a vapor deposition apparatus, for flash evaporation, i.e. having a crucible for flash evaporation. Particularly, the crucible for flash evaporation can be self-regulating with respect to the fill height of the crucible at a predetermined amount of material evaporated. Additionally or alternatively, a flow meter external to a conduit for liquid material and/or a valve having a regulating element external to the conduit for liquid material can be provided.

In the following, one or more evaporation concepts will be described for lithium as a material to be evaporated. According to some embodiments, which can be combined with other embodiments described herein, the evaporation concepts may also be applicable to other materials. Particularly, the evaporation concepts may also be applicable for highly reactive materials, for example, alkali metals or alkaline earth metals. Further, the evaporation concepts may be beneficially used for very high deposition rates resulting in layer thicknesses of a few microns or above on a roll-to-roll coater.

For the evaporation concept according to embodiments of the present disclosure, there is only a small amount of liquid Li in the crucible, which is evaporated in a very short time (flash evaporator). The evaporation material is continuously fed into the crucible, for example, by a dosing pump. According to embodiments of the present disclosure, for flash evaporation, the evaporation rate is controlled by the amount of material provided to the crucible, for example, by the amount of material provided by the dosing pump and/or the flow rate of liquid material into the crucible. The evaporation rate is not controlled by the temperature of the crucible.

Flash evaporation can be beneficial since flash evaporation allows in principle a continuous operation for a nearly infinite timeframe. Additionally or alternatively, deposition rate control can be more easily measured as compared to a temperature control of the crucible combined with a deposition rate measurement, for example, with the quartz crystal microbalance (QCM), wherein a QCM has to be exchanged or regenerated frequently. This is particularly true for embodiments of the present disclosure providing a vapor deposition apparatus with a close to full material utilization. The deposition rate may essentially correspond to the rate of liquid material provided to the crucible.

According to some embodiments, the evaporation can be provided by flash evaporation particularly at temperatures of 600° C. or above. For example, the temperature can be 800° C. or above. Before flash evaporation, the liquefied material is maintained at a temperature of 190° C. to 300° C. above the melting point of the material to be deposited, e.g. 373° C. to 483° C. for metallic lithium.

According to some embodiments, which can be combined with other embodiments described herein, a crucible for flash evaporation includes only a small amount of material to be evaporated in the evaporation area. For example, the evaporation area can have a volume of 200 cm³ or below and/or the amount of material, for example, lithium can have a volume of 10 cm³ or below.

The liquid material to be evaporated can be dispensed by a dosing pump into the evaporation crucible, where the material, for example, lithium is evaporated. The dosing pump may define the amount of liquid material provided to the crucible for flash evaporation. The evaporation rate is defined by the dosing pump or the flow rate of the liquid material and not by the temperature of the crucible.

According to some embodiments, methods of evaporation or apparatuses for evaporation of a material are provided, particularly of an alkali metal or alkaline earth metal. A first chamber configured to liquefy the material is provided. The first chamber comprises a gas inlet configured for an inlet of a gas in the first chamber, wherein particularly a pressure control of the gas can be provided. For example, the gas can be an inert gas such as Argon. An evaporation zone configured to flash evaporate the liquefied material is provided in a second chamber. A line or conduit providing a fluid communication between the first chamber and evaporation zone is provided. The flow rate of the liquid material in the line or conduit defines the deposition rate. The flow rate can be adjusted according to embodiments of the present disclosure. According to some embodiments, which can be combined with other embodiments described herein, the evaporation zone can be provided in a crucible. The crucible can be included in an evaporator, particularly an evaporator having a plurality of nozzles, such as a one-dimensional array of nozzles or two-dimensional array of nozzles.

According to some embodiments, which can be combined with other embodiments described herein, the evaporator may include a crucible and an enclosure in fluid communication with the crucible. The enclosure, i.e. a distribution enclosure, can be a vapor distribution pipe or a vapor distribution showerhead. The vapor can exit the enclosure through the plurality of nozzles provided in or at a wall of the enclosure. Particularly, a pressure within the enclosure is at least one or of magnitude higher as compared to the pressure in the second chamber, for example, a vacuum chamber, in which the evaporator is at least partially disposed.

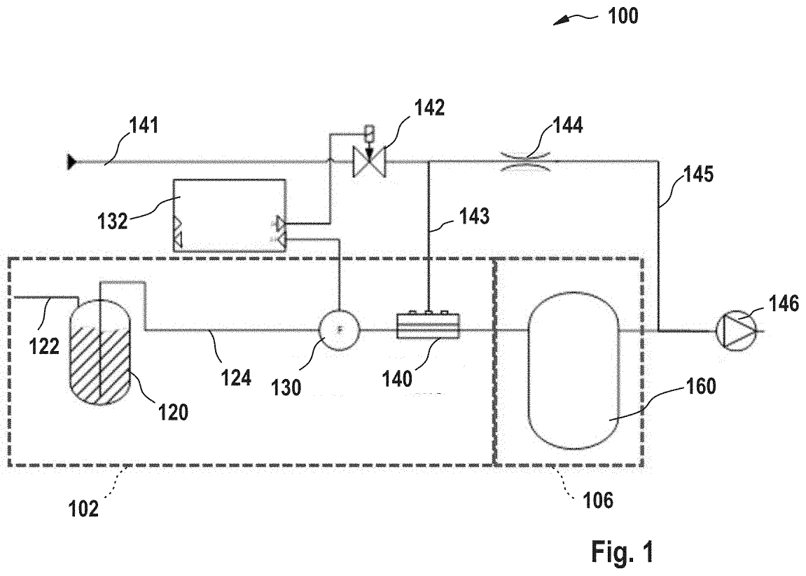

FIG. 1 shows a vapor deposition apparatus 100. The vapor deposition apparatus includes a first compartment indicated by dashed line 102. The first compartment is configured to maintain temperatures above the melting temperature of the material to be evaporated. For example, for lithium, a first temperature of the first compartment can be 190° or above, for example, 220° or above. Atmospheric conditions are provided in the first compartment. According to some embodiments, which can be combined with other embodiments described herein, the atmospheric conditions can be provided with a relative humidity of 2% or below, such as 1% or below, or even 0.5% or below. Accordingly, the first compartment may include a dehumidifier, particularly a dehumidifier configured to provide the relative humidity described above.

Reducing the humidity in the first compartment may be particularly useful for evaporating highly reactive materials, for example, alkali metals or alkaline earth metals, such as lithium.

A tank 120 is provided for liquefying the material to be evaporated. A gas conduit 122 is in fluid communication with the tank 120. A gas, for example, an inert gas, can be disposed in the tank 120. A pressure control can be provided for the gas conduit 122 to generate overpressure in the tank. The liquid material to be deposited in an evaporation zone is guided through the conduit 124. The overpressure in the tank 120 moves the liquid material through the line or conduit 124. According to some embodiments, which can be combined with other embodiments described herein, the pressure in the tank 120 can be controlled to be constant during evaporation. The pressure in the tank 120 may not be utilized to adjust the deposition rate.

A flow meter 130 measures the flow rate of the liquid material in the line or conduit 124. The flow meter 130 is connected to a controller 132. For example, the controller can be a PID controller. According to some embodiments, which can be combined with other embodiments described herein, the controller is configured for closed loop control. The flow rate measured by the flow meter 130 is provided as an input for the controller 132. The controller 132 adjusts the flow valve 140 to adjust the flow rate in the line or conduit 124. The liquid material is provided with a predetermined flow rate into the processing chamber 160. The process chamber 160 includes the evaporation zone configured for flash evaporation. The predetermined flow rate of a liquid material in the conduit 124 defines the deposition rate of the process chamber.

According to some embodiments, which can be combined with other embodiments described herein, the process chamber 160 can be provided under vacuum conditions. At least the evaporator in the process chamber can additionally be provided at high temperatures, for example, 500° C. or above, such as 600° C. to 800° C. The area including the process chamber 160 is indicated by dashed line 106 in FIG. 1. The process chamber 160 can be a vacuum chamber. According to some embodiments, the area (see dashed line 106) can be provided as a vacuum chamber and the process chamber 160 can be provided within the vacuum chamber.

According to embodiments of the present disclosure, the flow meter 130 can be disposed external to the conduit for the liquid material and/or the flow valve 140 can have a regulating element external to the conduit for the liquid material. Measuring the flow from outside the conduit and regulating the flow from outside the conduit reduces the probability of liquid material attaching to components within the conduit, which may result in clogging of the conduit. Unwanted clogging of the conduit is a highly critical situation particularly for highly reactive materials such as lithium or the like.

According to embodiments of the present disclosure, a flow valve, is provided for the vapor deposition apparatus. The flow valve may be membrane flow valve. No moving components are provided in the conduit for a membrane flow valve. Alternatively, a motor driven flow valve may be used. The flow valve can provide a constant flow of liquid material, for example, liquid lithium.

The flow valve 140 includes a membrane. The membrane is configured to adjust the cross-sectional area of the conduit 124 and/or may form a portion of the conduit 124. A gas, for example, an inert gas such as argon is provided in a conduit 141. The control valve 142 adjusts the pressure of the gas in the conduit 143 between the control valve and the flow valve 140. The pressure of the gas in the conduit 143 actuates the movable membrane of the flow valve 140. An increased pressure in the conduit 143 can reduce the cross-sectional area in the flow valve 140, i.e. the cross-sectional area of the conduit 124.

A flow restriction element 144 is in fluid communication with the conduit 143. A conduit 145 can be in fluid communication with the flow restriction element 144 and a pump. The flow restriction element 144 releases the pressure in the conduit 143. The gas passing through the flow restriction element 144 can be pumped by the vacuum pump 146. For example, the vacuum pump 146 can be a vacuum pump utilized for at least partially evacuating the vacuum chamber for the process region. The flow restriction element 144 provides a leakage of the conduit 143, particularly a constant leakage. Accordingly, the pressure in the conduit 143 can be reduced. The reduce pressure increases the cross-sectional area in the flow valve 140.

According to some embodiments, which can be combined with other embodiments described herein, the first compartment 102 can be provided with a thermal insulation at the interface to the first compartment or at least partially around the first compartment. Accordingly, the temperature within the first compartment can be above the melting temperature of the material to be evaporated, particularly constantly above the melting temperature. The one or more components within the compartment, particularly the components in contact with the material to be evaporated, can also be provided above the melting temperature. Blocking of the material, e.g. lithium can be avoided. For example, lines such as conduit 122 or conduit 143 can be provided with a material being a bad heat conductor, e.g. stainless steel. For example, the conduit 143 can have an insulator at the interface to the first compartment 102.

A closed loop control circuit can be provided by the flow meter 130, the controller 132, the control valve 142, the flow valve 140, and the flow restriction element 144.

According to some embodiments, which can be combined with other embodiments described herein, the flow meter 130 can be external to the conduit, i.e. the measurement is provided from outside a conduit in which the material to be evaporated flows. According to some embodiments, the flow meter can be a Coriolis flow meter, such as a Coriolis mass flow meter. The Coriolis flow meter is based on the Coriolis force. A tube or a portion of the conduit is energized by a vibration. The excitation vibrates the tube or the portion of the conduit. The mass of the medium flowing through the tube changes the tube vibration and may, particularly, introduce phase shift in the vibration. For example, the tube may twist due to the Coriolis force. The resulting change in vibration, such as a phase shift, can be measured. The measurement results in an output correlating with the mass flow in the tube or conduit. For example, the output can be proportional to the flow. Accordingly, the flow rate in the conduit can be measured while reducing or avoiding the risk of clogging of the conduit.

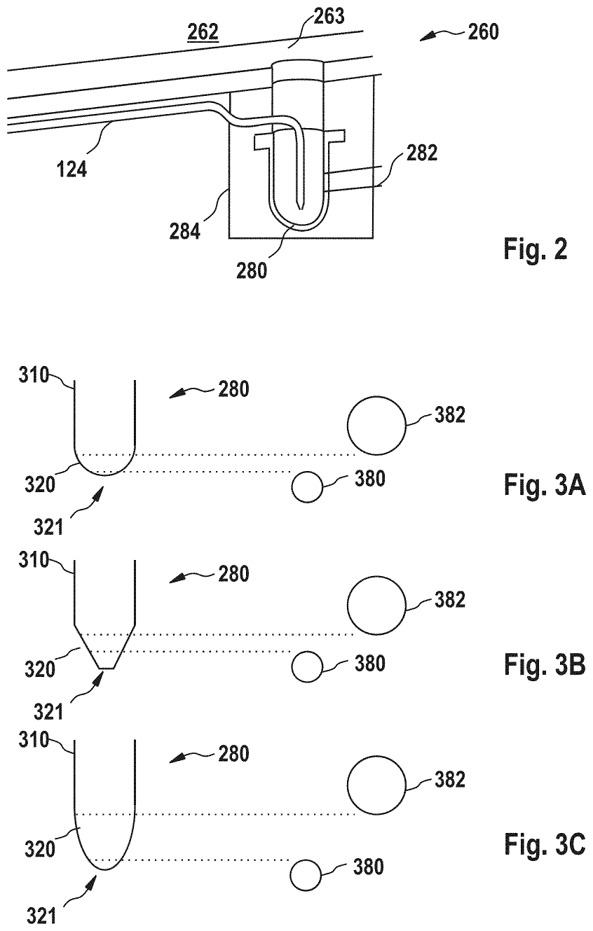

FIG. 2 shows a portion of an evaporator 260. The conduit 124 provides the liquid material to be evaporated into the crucible 280. According to some embodiments, which can be combined with other embodiments described herein, the material may be lithium or any other materials described herein. The material is evaporated in the crucible 280. The crucible is in fluid communication with enclosure 262. One wall 263 of the enclosure 262 is shown in FIG. 2. A further wall of the enclosure 262, for example, a wall opposite the wall 263 may include a plurality of nozzles to guide the materials towards the substrate.

Electrical lines 282 of a thermo couple are provided to measure the temperature of the crucible. The crucible 280 can be provided with an electrical heater for heating the crucible. The crucible may be electrically heated or connected to another electrical heater. For example, the crucible can be connected to a graphite heater. For example, the graphite heater can at least partially surround the crucible. According to some embodiments, the evaporation can be provided by flash evaporation. The crucible temperature may be 600° C. or above. For example, the temperature can be 800° C. or above. A heat shield 284 can be provided at least partially around the crucible to reduce heat loss of the crucible, to reduce heat radiation towards other components, and/or to increase temperature stability of the crucible. As described above, the temperature may be stabilized since the temperature is not utilized to control the deposition rate.

According to embodiments of the present disclosure, the crucible can be shaped for self-regulating flash evaporation. Different cross-sections of different shapes of crucibles are described in FIGS. 3A to 3C.

According to embodiments described herein, the crucible 280 includes one or more sidewall 310. For example, a sidewall 310 may form a cylinder. According to some embodiments, which can be combined with other embodiments described herein, a cylinder can be open at the top to allow for fluid communication with the enclosure 262. The crucible 280 further includes a reservoir portion 320 below the one or more sidewall 310. The reservoir portion 320 is closed at the bottom 321 of the reservoir portion.

According to some embodiments, which can be combined with other embodiments described herein, the reservoir portion can have a semi-circular cross-section (see FIG. 3A), a cross-section corresponding to a portion of an oval (see FIG. 3C), or a tapered cross-section (see FIG. 3B). For example, the tapered cross-section can be a cone or a truncated cone as shown in FIG. 3B.

As illustrated in FIGS. 3A to 3B, in a top view, the reservoir portions have a lower cross-section 380 that is smaller than an upper cross-section 382. As shown in FIG. 2, the crucible and the reservoir portion can be filled with liquid material through the conduit 124 from the top of the reservoir portion. Depending on the amount of liquid material inserted in the crucible, a fill height of the liquid material in the reservoir portion is generated.

According to embodiments of the present disclosure, the fill height and/or the rate of flash evaporation is self-regulating, particularly based on the flow rate of liquid material into the crucible. For a comparably low flow rate of liquid material in the crucible, the fill height is low, for example, close to the lower cross-section 380. Accordingly, the liquid material is in contact with a comparably small surface area of the crucible. There is an equilibrium between a given flow rate of liquid material and the resulting fill height.

For a first predetermined flow rate, a higher (overly high) fill height in the reservoir portion results in a higher evaporation rate due to the larger cross-section closer to the upper cross-section 382. More material is evaporated than filled in the crucible by flash evaporation. Accordingly, the fill height reduces until the equilibrium is generated. Similarly, if a second predetermined flow rate is provided at a lower (overly low) fill height in the reservoir portion, the lower fill height, i.e. close to the smaller, lower cross-section 380, results in an increase in the fill height due to the smaller evaporation surface until an equilibrium is generated. In light of the above, the crucible is self-regulating for various flow rates of liquid material. Accordingly, in the event of flow rate fluctuations in the flow rate of the liquid material, the crucible cannot be overly filled. The fill height is self-regulating in case of fluctuations. A corresponding surface area is provided in the reservoir portion having a variation of the crucible size in cross-section along the fill height, wherein the fill height in the crucible provides the surface area for evaporation and generates an equilibrium with the flow rate of liquid material inserted into the crucible.

According to some embodiments, which can be combined with other embodiments described herein, the temperature of the crucible can be provided to a have a low fill height. The fill height at this temperature is self-regulating in the event of fluctuations in the flow rate of liquid material. The deposition rate depends on the flow rate of the liquid material.

FIGS. 3A to 3B show crucibles 280 with one or more sidewall 310 and a reservoir portion 320, wherein the cross-section of the crucible, i.e. the cross-section in a top view of an inner wall of the crucible, is circular. According to yet further modifications, which can be combined with other embodiments described herein, the cross-section in a top view of the crucible, i.e. an inner wall of the crucible may also have another shape, for example, rectangular, or polygonal. For a polygonal top cross-section, particularly a tapered cross-section side view, as shown in FIG. 3B, may be provided.

According to some embodiments, which can be combined with other embodiments described herein, the shape of the evaporation surface of the crucible is provided such that the size of the evaporation surface increases with liquid content, i.e. the fill height. The size of the evaporation surface may directly increase with the liquid content. Accordingly, different flow rates can be evaporated at a constant or nearly constant crucible temperature. For a predetermined evaporation rate, the fill height, i.e. the size of the liquid pool in the crucible, is a function of the evaporation temperature, i.e. the temperature of the crucible. The fill height or the size of the pool of liquid material can be adjusted by the crucible temperature. The crucible is provided at a high temperature for flash evaporation as described herein. The crucible temperature does not influence the evaporation rate or deposition rate, respectively, since an equilibrium fill height will be established as described above.

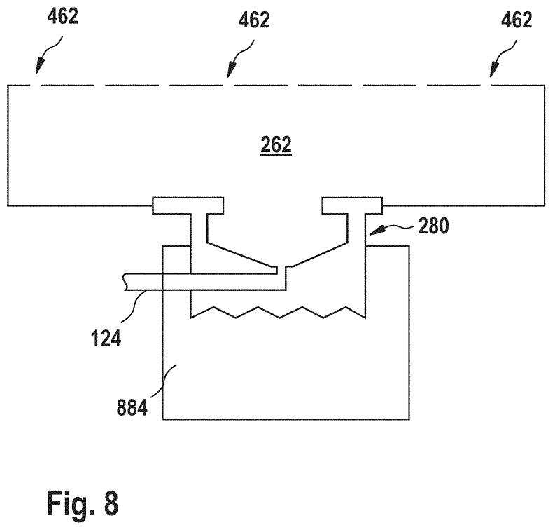

FIG. 8 shows an evaporator according to yet further embodiments. The implementations described with respect to FIG. 8 may also be combined with other embodiments of the present disclosure. The crucible 280 is provide in fluid communication with the enclosure 262, i.e. a distribution enclosure. The vapor can exit the enclosure via nozzles 462. The liquid material, for example, liquid lithium is filled from the bottom of the crucible. The liquid material can be provided by conduit 124. The crucible can be heated with an electrical heater 884. For example, the crucible can be connected to a graphite heater. As shown in FIG. 8, the surface between the electrical heater and the crucible can be enlarged by protrusions and/or recesses. Filling the crucible from the bottom may have the advantage that splashing of liquid material in the pool of material to be flash evaporated is avoided.

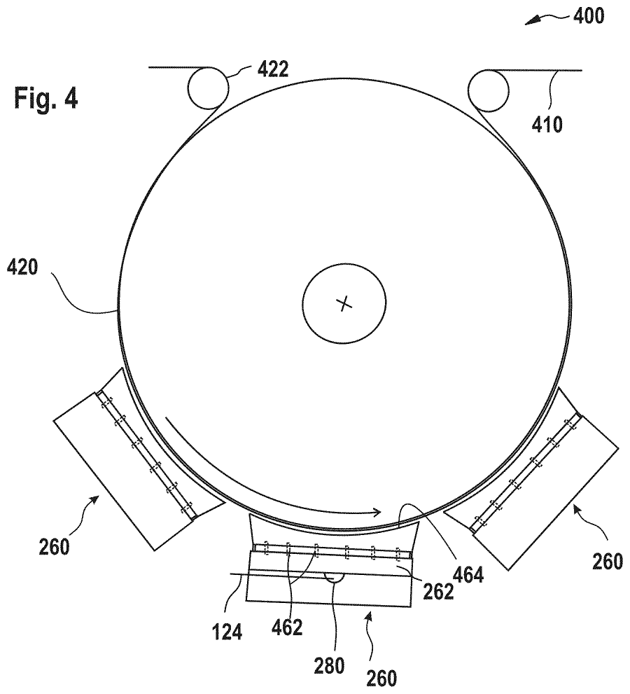

FIG. 4 shows a schematic view of a further vapor deposition apparatus 400 having one or more evaporators according to embodiments of the present disclosure. The apparatus provides a processing direction of a web 410 or a foil from below a processing drum 420. The web 410 is guided by rollers 422 on the processing drum 420. The processing drum rotates as indicated by the arrow and moves the web through the processing regions of the evaporators 260. FIG. 4 shows three evaporators 260.

According to some embodiments, the one or more evaporators 260 can include a crucible 280 evaporating the liquid material that is guided through the conduit 124 in the crucible. The vapor is distributed in the enclosure 262. The vapor is guided through the nozzles 462 towards the web provided on the processing drum 420.

According to some embodiments, which can be combined with other embodiments described herein, a heated shield 464 can be provided. The evaporators and the processing drum are at least partially disposed within the vacuum chamber (not shown in FIG. 4). The processing regions of the evaporators 260 are within the vacuum chamber. The enclosure 262 acting as the vapor distribution enclosure can have a pressure inside the enclosure, i.e. a vapor pressure, that is at least one magnitude higher as compared to the pressure in the vacuum chamber or the processing region, respectively.

The heatable shield 464 is heatable, such that vapor condensation on the heatable shield 464 can be reduced or prevented when the heatable shield is heated to an operation temperature, e.g. an operation temperature of 500° C. or more in some embodiments, such as 500° C. to 600° C. Preventing vapor condensation on the heatable shield is beneficial because cleaning efforts can be reduced. Further, a coating on the heatable shield 464 may change the dimensions of a coating window that is provided by the heatable shield. In particular, if a gap in the range of only few millimeters, e.g. of about 1 mm or less, is provided between the heatable shield 464 and the substrate support, a coating on the heatable shield would lead to a change in the gap dimensions and hence to an undesired change in an edge shape of a coating layer deposited on the substrate. Further, source material utilization can be improved when no source material accumulates on the heatable shield. Specifically, essentially all the source material propagating inside the vapor propagation volume can be used for coating the substrate surface if the heatable shield is heated to the operation temperature that may be above a vapor condensation temperature.

A “vapor condensation temperature” as used herein may be understood as threshold temperature of the heatable shield above which the vapor does no longer condense on the heatable shield. The operation temperature of the heatable shield 464 may be at or (slightly) above the vapor condensation temperature. For example, the operation temperature of the heatable shield may be between 5° C. and 50° C. above the vapor condensation temperature in order to avoid an excessive heat radiation toward the substrate support. It is to be noted that the vapor condensation temperature may depend on the vapor pressure. Since the vapor pressure downstream of the plurality of nozzles in the vapor propagation volume is lower than the source pressure inside a crucible and/or inside a distributor of the vapor source, the vapor inside the vapor source may condense already at a lower temperature than the vapor inside the vapor propagation 20. The “vapor condensation temperature” as used herein relates to the temperature of the heatable shield downstream of the plurality of nozzles in the vapor propagation volume 20 that avoids a vapor condensation on the heatable shield. The “evaporation temperature” as used herein relates to a temperature inside the vapor source upstream of the plurality of nozzles at which the source material evaporates. The evaporation temperature within the vapor source is typically higher than the vapor condensation temperature inside the vapor propagation volume. For example, the evaporation temperature inside the vapor source may be set to a temperature above 600° C., such as 750° C. to 850° C., whereas the vapor condensation temperature downstream of the plurality of nozzles may be below 600° C., e.g. from 500° C. to 550° C., if Lithium is evaporated. In embodiments described herein, the temperature inside the vapor source may be 600° C. or more, whereas the operation temperature of the heatable shield may be set at less than 600° C., e.g. from 500° C. to 550° C. during vapor deposition.

Vapor hitting the heatable shield that is provided at the operation temperature of, e.g. 500° C. to 550° C., may be immediately re-evaporated or reflected from the heatable shield surface, such that the respective vapor molecules end up on the substrate surface rather than on the heatable shield surface. Material accumulation on the heatable shield can be reduced or prevented, and cleaning efforts can be reduced.

The “heatable shield” may also be referred to herein as a “temperature-controlled shield” since the temperature of the heatable shield can be set to the predetermined operation temperature during the vapor deposition, reducing or preventing the vapor condensation on the heatable shield. In particular, the temperature of the heatable shield can be controlled to be maintained in a predetermined range. A controller and a respective heating arrangement controlled by the controller may be provided for controlling the temperature of the heatable shield during vapor deposition.

Embodiments of the present disclosure relate to a vapor apparatus, particularly for high deposition rates. For example, for manufacturing of a thin-film battery, deposition rates of several micrometers, such as 10 μm or above are beneficial for cost-efficient mass production. Evaporators that are commonly used may provide a material utilization of around 60% to 80%. For high deposition rates, an accumulation of 20% or 40% of the evaporated material on components of the vapor deposition apparatus, for example, a shielding would result in fast growth of material layers on the components. Maintenance cycles would be very short to remove accumulated material on the components of the vapor deposition apparatus.

Accordingly, an evaporator or a vapor deposition apparatus according to embodiments of the present disclosure provide the material utilization of at least 90%, particularly of 95% or above. The material is flash evaporated. No material accumulation occurs within the crucible 280. The enclosure 262 and the nozzles 462 are provided at high temperatures to also avoid or reduce material accumulation. The heated shield 464 is also provided at a temperature above the condensation temperature. Accordingly, most or all of the material provided in the evaporator 260 is deposited on the substrate, for example the web 410.

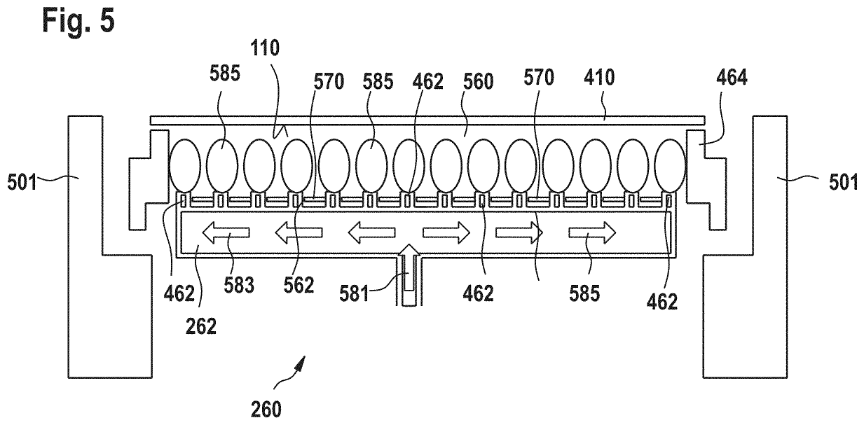

According to embodiments of the present disclosure, apparatuses and methods for coating by evaporation in the vacuum chamber are provided. For depositing a substrate with source material by evaporation, the source material may be heated above the evaporation or sublimation temperature of the source material. Embodiments of the present disclosure result in reduced condensation on surfaces, for example surfaces other than the substrate that may have lower temperatures. Such surfaces may for example be a chamber wall 501 of a vacuum chamber shown in FIG. 5.

FIG. 5 shows a schematic view of a further vapor deposition apparatus having one or more frames or heated shields according to embodiments of the present disclosure. The embodiments described with respect to FIG. 5 may be combined with other aspects, details, embodiments and features described in the present disclosure. A material, i.e. a source material, to be deposited is evaporated within the crucible by heating the material. The material can include, for example, metal, in particular lithium, metal alloys, and other vaporizable materials or the like which have a gaseous phase under given conditions. According to yet further embodiments, additionally or alternatively, the material may include magnesium (Mg), ytterbium (YB) and lithium fluoride (LiF). The evaporated material generated in the crucible can enter the enclosure 262, e.g. a distributor along the direction represented by the arrow 581. The distributor can, for example, include a channel or a tube which provides a transport system to distribute the evaporated material along the width and/or the length of the deposition apparatus. The distributor can have the design of a “shower head reactor”.

As exemplarily shown, the evaporated source material can be guided within the distributor along the directions 583 and 585. The directions 583 and 585 can be essentially parallel to a substrate surface 110 or parallel to walls 263 of the enclosure 262. In the event of a coating drum of a roll-to-roll coater, the direction 583 and 585 may also be curved according to a tangent of the coating drum at the shortest distance of the source and the drum. The evaporated material is ejected from the evaporator 260 by means of nozzles 462 to the interior of the vacuum chamber. The nozzles 462 can be arranged within the openings 562 of a heat shield 570. The evaporated material 585 ejected by the nozzles is deposited on the substrate surface 110 of the substrate, e.g. a web 410, to form a coating on the substrate. The evaporator provides a processing region 560.

The heat shield 570 reduces the radiant heat coming from the evaporator, towards the substrate. According to embodiments of the present disclosure, the heat shield 570 includes openings 562. According to some embodiments, which can be combined with other embodiments described herein, the nozzles 462 of the distributor can extend through the openings of the heat shield 570.

According to embodiments which can be combined with other embodiments describe herein, the evaporated material can include or can consist of lithium, Yb, or LiF. According to embodiments which can be combined with other embodiments described herein, the temperature of the evaporator and/or of the nozzles can be at least 600° C., or particularly between 600° C. and 1000° C., or more particularly between 600° C. and 800° C. According to embodiments which can be combined with other embodiments described herein, the temperature of the heated shield can be between 450° C. and 600° C., particularly around 550° C. with a deviation of +−10° C. or less.

According to embodiments which can be combined with other embodiments described herein, the temperature of the heated shield is lower than the temperature of the evaporator by at least 100° C., in particular is lower up to 300° C., more particularly is lower by at least 100° C. and up to 300° C.

Furthermore, by heating the heat shield, the material which is deposited on the surface of the heat shield, for example, by stray coating can also be re-evaporated. The stray coated material on the heat shield can be advantageously removed by re-evaporation as described herein. Furthermore, by re-evaporating material from the heat shield, the coating on the substrate can also be made more uniform and material utilization can be increased.

The heated shield can be a temperature-controlled shield. The temperature-controlled shield can improve the deposition process within the interior of the vacuum chamber. The temperature of the temperature-controlled shield can be high enough to reduce the condensation of the evaporated material on the chamber walls. Furthermore, the temperature of the temperature-controlled or heated shield can also be low enough to keep the heat load for the substrate low.

Furthermore, stray coated material on the heated shield can be re-evaporated to be deposited on the substrate. Moreover, by re-evaporating material from the heat shield, the coating on the substrate can also be made more uniform and material utilization can be improved. By reducing the stray coating on the chamber walls by the heated shield, the vacuum deposition chamber can be operated with higher throughputs of evaporated material which further enhance the production rate of coated substrates.

The crucible, the vapor deposition apparatus, the method of coating a substrate in a vacuum chamber, and the method of manufacturing an unknown of a battery may be particularly useful for depositing lithium. The lithium may be deposited on a thin web or foil to improve mass production of thin-film batteries.

Lithium may for example be deposited on a thin copper foil to generate an anode of a battery. Further, a layer including graphite and at least one of silicon and a silicon oxide may be provided on a thin web or foil. The web or foil may further include a conductive layer or may consist of a conductive layer serving as a contact surface of the anode. Lithium deposited on the layer on the web may provide prelithiation of the layer including graphite and at least one of silicon and a silicon oxide.

For mass production, high deposition rates are beneficial. Yet, the webs or foils, particularly in a roll-to-roll deposition process are very thin. The heat transfer on the substrate is dominated by condensation energy of the evaporated material. Further, heat removal from the substrate in a vacuum process is dominated by heat conduction. Accordingly, the vapor deposition apparatus according to embodiments of the present disclosure beneficially includes a coating drum configured to effectively remove heat from the substrate.

According to some embodiments, which can be combined with other embodiments described herein, the coating drum may be a gas cushion coating drum. The gas cushion coating drum provides a cooling gas between the surface of the drum and the substrate. For example, the drum and the cooling gas can be cooled to temperatures below room temperature. Heat can be removed from the substrate to allow for higher deposition rates without damaging the thin foil or web on which the material is deposited.

For a gas cushion roller, a first subgroup of gas outlets, i.e., the open gas outlets, can be provided in a web guiding region of the processing drum. A second subgroup of gas outlets, i.e., closed gas outlets, are provided outside the web guiding region. Since gas is only emitted in the web guiding region where the gas is needed to form the hover cushion, no or little gas is directly emitted into a region not overlapped by the web, waste of gas may be reduced and/or a better vacuum may be maintained at lesser strain on the pump system.

According to some embodiments, which can be combined with other embodiments described herein, additionally or alternatively to the subgroups of gas outlets, the outer surface of the processing drum may be coated with a microporous surface. The microporous surface may allow for a small amount of cooling gas to flow from inside the processing drum to the surface of the processing drum. The cooling gas may form a gas cushion between the processing drum and the web or foil guided over the processing drum for material deposition thereon.

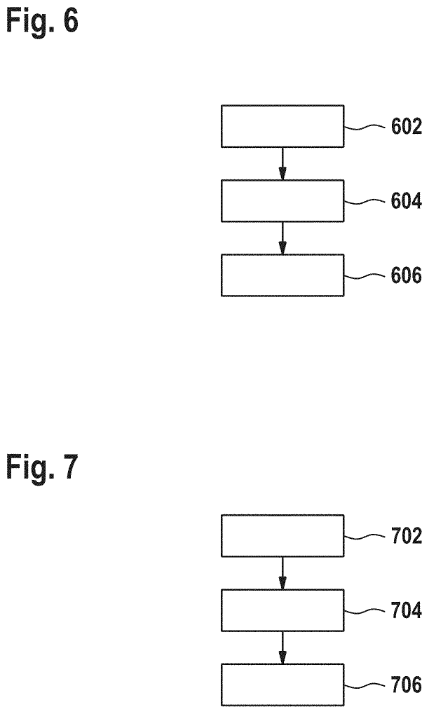

FIG. 6 shows a flowchart illustrating a method of coating a substrate in a vacuum chamber. At operation 602, the method includes guiding a liquid material into a crucible for flash evaporation. According to some embodiments, the crucible may be a crucible for flash evaporation according to embodiments of the present disclosure. The liquid material is flesh evaporated in the crucible in operation 604. The flow rate of the liquid material is measured at operation 606 to control the deposition rate. For example, the flow rate can be measured with the flowmeter according to embodiments of the present disclosure. Further, the flow rate of the liquid material may directly correlate with the deposition rate since a vapor deposition apparatus as described herein may provide the material utilization of 95% or above.

According to some embodiments, which can be combined with other embodiments described herein, the crucible temperature is constant and, particularly not utilized for adjusting the deposition rate. The fill height in the crucible depends on the flow rate of the liquid material in the crucible.

For an evaporator as described herein, the evaporated material is guided from the crucible into a distribution enclosure, such as the enclosure 262 shown in FIGS. 3, 4 and 5. The evaporated material is guided from the distribution enclosure through a plurality of nozzles on or towards the substrate. For example, the substrate can be a thin web or foil, particularly of a roll-to-roll vacuum deposition apparatus. In order to provide very high material utilization, the material to be deposited on the substrate may be re-evaporated by a temperature control shield disposed between the distribution enclosure and the substrate.

FIG. 7 shows a flowchart illustrating a method of manufacturing an anode of a battery. According to some embodiments, the method of manufacturing an anode of a battery may include a method for coating a substrate in a vacuum chamber described with respect to FIG. 6.

According to one embodiment, as shown in operation 702, the method includes guiding a web or foil in a vapor deposition apparatus according to embodiments of the present disclosure. The vapor or foil may comprise or consists of an anode layer for a battery, particularly a thin-film battery. At operation 704, a liquid lithium-containing material is provided in an evaporator of the vapor deposition apparatus. At operation 706, a lithium-containing material or lithium is deposited on the web with the vapor deposition apparatus.

According to some embodiments, which can be combined with other embodiments described herein, for the method of manufacturing an anode of a battery, the web comprises copper or consists of copper. According to some implementations, the web may further comprise graphite and silicon and/or silicon oxide. For example, the lithium may pre-lithiate the layer including graphite and silicon and/or silicon oxide.

In particular, the following embodiments are described herein:

Embodiment 1. A crucible for flash evaporation of a liquid material, comprising: one or more sidewalls; and a reservoir portion below the one or more sidewalls, the reservoir portion having a first cross-section of a first size and a second cross-section above the first cross-section of a second size, the second size being larger than the first size.
Embodiment 2. The crucible according to embodiment 1, further comprising: an opening for a conduit guiding the liquid material in the crucible.
Embodiment 3. The crucible according to embodiment 2, wherein the opening is provided in the one or more sidewalls or at the bottom of the reservoir portion.
Embodiment 4. The crucible according to any of embodiments 1 to 3, wherein the one or more sidewalls and the reservoir portion are integrally formed.
Embodiment 5. The crucible according to any of embodiments 1 to 4, wherein the crucible comprises or consists of stainless steel, Mo, Ta or combinations thereof.
Embodiment 6. The crucible according to any of embodiments 1 to 5, further comprising: a vapor passage for the evaporated material, the vapor passage being provided at an upper end of the one or more sidewalls.
Embodiment 7. The crucible according to any of embodiments 1 to 6, wherein the reservoir portion has a further cross-section being selected from the group consisting of: a semi-circular cross-section, a cross-section corresponding to a portion of an oval, and a tapered cross-section, particularly a cross-section of a cone or a truncated cone.
Embodiment 8. The crucible according to any of embodiments 1 to 7, wherein at least one of the first cross-section and the second cross-section is a circle, an oval, or a polygon.
Embodiment 9. The crucible according to any of embodiments 1 to 8, wherein the first size of the first cross-section is a first perimeter of the first cross-section and the second size of the second cross-section is a second perimeter of the second cross-section.
Embodiment 10. A vapor deposition apparatus, comprising: a crucible according to any of embodiments 1 to 9.
Embodiment 11. The vapor deposition apparatus according to embodiment 10, further comprising: a flow meter with a measuring unit external to a conduit for guiding the liquid material.
Embodiment 12. The vapor deposition apparatus according to embodiment 11, wherein the flow meter is a Coriolis flow meter.
Embodiment 13. The vapor deposition apparatus according to any of embodiments 10 to 12, further comprising: a flow valve having a regulating element external to the conduit for the liquid material.
Embodiment 14. The vapor deposition apparatus according to embodiment 13, further comprising: a control valve configured to adjust a gas pressure at the flow valve.
Embodiment 15. The vapor deposition apparatus according to embodiment 14, further comprising: a flow restriction element configured to reduce the gas pressure at the flow valve.
Embodiment 16. The vapor deposition apparatus according to any of embodiments 14 to 15, further comprising: a controller configured to provide a closed loop control, the controller being connected to the flow meter and the control valve.
Embodiment 17. A vapor deposition apparatus configured to evaporate an alkali metal and/or alkaline earth metals, particularly lithium, comprising: a flow meter with a measuring unit external to a conduit for the liquid material.
Embodiment 18. The vapor deposition apparatus according to embodiment 17, wherein the flow meter is a Coriolis flow meter.
Embodiment 19. The vapor deposition apparatus according to any of embodiments 17 to 18, further comprising: a flow valve having a regulating element external to the conduit for the liquid material.
Embodiment 20. The vapor deposition apparatus according to embodiment 19, further comprising: a control valve configured to adjust a gas pressure at the flow valve.
Embodiment 21. The vapor deposition apparatus according to embodiment 20, further comprising: a flow restriction element configured to reduce the gas pressure at the flow valve.
Embodiment 22. The vapor deposition apparatus according to any of embodiments 20 to 21, further comprising: a controller configured to provide a closed loop control, the controller being connected to the flow meter and the control valve.
Embodiment 23. The vapor deposition apparatus according to any of embodiments 10 to 22, further comprising: a vacuum chamber for depositing the material on a substrate in the vacuum chamber.
Embodiment 24. The vapor deposition apparatus according to any of embodiments 10 to 23, further comprising: a vapor distribution enclosure in fluid communication with the crucible, particularly a crucible according to any of embodiments 1 to 9, the vapor distribution enclosure having a plurality of nozzles.
Embodiment 25. The vapor deposition apparatus according to any of embodiments 23 to 24, wherein the pressure within the enclosure is at least one order of magnitude higher than the pressure in the vacuum chamber.
Embodiment 26. The vapor deposition apparatus according to any of embodiments 10 to 25, further comprising a heated shield.
Embodiment 27. The vapor deposition apparatus according to any of embodiments 10 to 26, further providing a processing drum configured to support the substrate during material deposition.
Embodiment 28. A method of coating a substrate in a vacuum chamber, comprising: guiding a liquid material into a crucible for flash evaporation, particularly a crucible according to any of embodiments 1 to 9; flash evaporating the liquid material in the crucible; and measuring a flow rate of the liquid material to control a deposition rate of the material on the substrate.
Embodiment 29. The method according to embodiment 28, wherein the fill height in the crucible depends on the flow rate of the liquid material.
Embodiment 30. The method according to any of embodiments 28 to 29; further comprising: guiding the evaporated material from the crucible into a distribution enclosure; and guiding the evaporated material from the distribution enclosure through a plurality of nozzles on the substrate.
Embodiment 31. The method according to any of embodiments 28 to 30, further comprising: re-evaporating material accumulated on a temperature-controlled shield disposed between the distribution enclosure and the substrate.
Embodiment 32. The method according to embodiment 30, further comprising: shielding chamber walls of the vacuum chamber with a temperature-controlled shield, wherein a temperature of the evaporator is higher than a temperature of the temperature-controlled shield; and shielding at least a portion of an evaporator with a heat shield being passively heated and wherein the temperature of the evaporator is higher than the temperature of the heat shield.
Embodiment 33. A method of manufacturing an anode of a battery, comprising: a method for coating a substrate in a vacuum chamber according to any of embodiments 28 to 32.
Embodiment 34. A method of manufacturing an anode of a battery, comprising:

guiding a web comprising or consisting of an anode layer in a vapor deposition apparatus according to any of embodiments 10 to 27; and depositing a lithium containing material or lithium on the web with the vapor deposition apparatus.

Embodiment 35. The method according to embodiment 34, wherein the web comprises copper.
Embodiment 36. The method according to embodiment 34, wherein the web comprises graphite and silicon and/or silicon oxide.
Embodiment 37. The method according to embodiment 36, wherein the anode layer is pre-lithiated.

While the foregoing is directed to embodiments, other and further embodiments may be devised without departing from the basic scope, and the scope is determined by the claims that follow.

1. A crucible for flash evaporation of a liquid material, comprising:
one or more sidewalls; and
a reservoir portion below the one or more sidewalls, the reservoir portion having a first cross-section of a first size and a second cross-section above the first cross-section of a second size, the second size being larger than the first size.

2. The crucible for flash evaporation of a liquid material according to claim 1, further comprising:
an opening for a conduit guiding the liquid material in the crucible.

3. The crucible for flash evaporation of a liquid material according to claim 2, wherein the opening is provided in the one or more sidewalls or at the bottom of the reservoir portion.

4. The crucible for flash evaporation of a liquid material according to claim 1, wherein the one or more sidewalls and the reservoir portion are integrally formed.

5. The crucible for flash evaporation of a liquid material according to claim 1, wherein the crucible comprises or consists of stainless steel, Mo, Ta or combinations thereof.

6. The crucible for flash evaporation of a liquid material according to claim 1, further comprising:
a vapor passage for the evaporated material, the vapor passage being provided at an upper end of the one or more sidewalls.

7. The crucible for flash evaporation of a liquid material according to claim 1, wherein the reservoir portion has a further cross-section being selected from the group consisting of:
a semi-circular cross-section, a cross-section corresponding to a portion of an oval, and a tapered cross-section.

8. The crucible for flash evaporation of a liquid material according to claim 1, wherein at least one of the first cross-section and the second cross-section is a circle, an oval, or a polygon.

9. The crucible for flash evaporation of a liquid material according to claim 1, wherein the first size of the first cross-section is a first perimeter of the first cross-section and the second size of the second cross-section is a second perimeter of the second cross-section.

10. A vapor deposition apparatus, comprising:
a crucible according to claim 1.

11. The vapor deposition apparatus according to claim 10, further comprising:
a flow meter with a measuring unit external to a conduit for guiding the liquid material.

12. The vapor deposition apparatus according to claim 11, wherein the flow meter is a Coriolis flow meter.

13. The vapor deposition apparatus according to claim 10, further comprising:
a flow valve having a regulating element external to the conduit for the liquid material.

14. The vapor deposition apparatus according to claim 13, further comprising:
a control valve configured to adjust a gas pressure at the flow valve.

15. The vapor deposition apparatus according to claim 14, further comprising:
a flow restriction element configured to reduce the gas pressure at the flow valve.

16. The vapor deposition apparatus according to claim 14, further comprising:
a controller configured to provide a closed loop control, the controller being connected to the flow meter and the control valve.

17. A vapor deposition apparatus configured to evaporate one of the group consisting of an alkali metal and alkaline earth metals, comprising:
a flow meter with a measuring unit external to a conduit for the liquid material.

18. The vapor deposition apparatus configured to evaporate one of the group consisting of an alkali metal and alkaline earth metals according to claim 17, further comprising:
a flow valve having a regulating element external to the conduit for the liquid material.

19. The vapor deposition apparatus according to claim 10, further comprising:
a vapor distribution enclosure in fluid communication with the crucible, the vapor distribution enclosure having a plurality of nozzles.

20. A method of coating a substrate in a vacuum chamber, comprising:
guiding a liquid material into a crucible according to claim 1 for flash evaporation;
flash evaporating the liquid material in the crucible; and
measuring a flow rate of the liquid material to control a deposition rate of the material on the substrate.
